(19) United States
(12) Patent Application Publication
(10) Pub. No.: US 2016/0177446 A1
(43) Pub. Date: Jun. 23, 2016

(54) Substrate Processing Apparatus, Method of Manufacturing Semiconductor Device and Non-Transitory Computer-Readable Recording Medium

(71) Applicant: Hitachi Kokusai Electric Inc., Tokyo (JP)

(72) Inventor: Shuhei SAIDO, Toyama (JP)

(21) Appl. No.: 14/802,491

(22) Filed: Jul. 17, 2015

(30) Foreign Application Priority Data
Dec. 18, 2014 (JP) 2014-256371

(51) Int. Cl. C23C 16/455

(52) U.S. Cl. CPC C23C 16/45548; C23C 16/45574; C23C 16/45565; C23C 16/45559; C23C 16/45557

(57) ABSTRACT

A substrate processing apparatus includes a process chamber, a substrate support, a first gas supply unit including a first gas dispersion unit, a second gas supply unit including a second gas dispersion unit, and a plurality of dispersion pipes connecting the process chamber and the second gas dispersion unit. An area of an inner surface of the second gas dispersion unit is smaller than a sum of an area of an inner surface of the first gas dispersion unit and areas of outer surfaces of the plurality of dispersion pipes. The substrate processing apparatus may reduce at least one of the amounts of residual first gas and residual second gas wherein the byproducts generated by the reaction between the residual first gas and the residual second gas hinder a desired chemical reaction in forming a film by supplying the first gas and the second gas in a cycle.

### CROSS REFERENCE TO RELATED APPLICATION

This application claims foreign priority under 35 U.S.C. §119(a)-(d) to Application No. JP 2014-0256371 filed on Dec. 18, 2014, entitled “SUBSTRATE PROCESSING APPARATUS, METHOD OF MANUFACTURING SEMICONDUCTOR DEVICE AND NON-TRANSITORY COMPUTER-READABLE RECORDING MEDIUM,” the entire contents of which are hereby incorporated by reference.

### FIELD OF THE INVENTION

The present invention relates to a substrate processing apparatus, a method of manufacturing a semiconductor device and a non-transitory computer-readable recording medium.

### BACKGROUND

Recently, there is a growing need to develop a technique of forming a film to a uniform thickness within a top surface of a substrate and on a plane of a pattern on the substrate, as semiconductor devices, e.g., integrated circuits (ICs), and particularly, dynamic random access memory (DRAM) have been developed to have a high integration degree and performance. Among techniques developed for this need, there is a method of forming a film on a substrate using a plurality of sources. According to the method, a conformal film having high step coverage may be formed to form, for example, a DRAM capacitor electrode having a high aspect ratio.

An unintended reaction may occur due to a first gas and a second gas in a method of forming a film by supplying the first and second gases in a cycle. Thus, the unintended reaction may prevent a film having desired characteristics from being formed and degrade characteristics of a semiconductor device.

### SUMMARY

It is a main object of the present invention to provide a substrate processing apparatus capable of improving the characteristics of a film to be formed on a substrate, a method of manufacturing a semiconductor device and a non-transitory computer-readable recording medium therefor.

According to one aspect of the present invention, there is provided a substrate processing apparatus including a process chamber configured to process a substrate; a substrate support configured to support the substrate; a first gas supply unit including a first gas dispersion unit configured to disperse a first gas; a second gas supply unit including a second gas dispersion unit configured to disperse a second gas; and a plurality of dispersion pipes connecting the process chamber and the second gas dispersion unit by penetrating an inside of the first gas dispersion unit, wherein an area of an inner surface of the second gas dispersion unit is smaller than a sum of an area of an inner surface of the first gas dispersion unit and areas of outer surfaces of the plurality of dispersion pipes.

According to another aspect of the present invention, there is provided a method of manufacturing a semiconductor device including: (a) supplying a first gas to a substrate accommodated in a process chamber through a first dispersion unit; and (b) supplying a second gas to the substrate through a second gas dispersion unit and a plurality of dispersion pipes connecting the process chamber and the second gas dispersion unit by penetrating an inside of the first gas dispersion unit, wherein an area of an inner surface of the second gas dispersion unit is smaller than a sum of an area of an inner surface of the first gas dispersion unit and areas of outer surfaces of the plurality of dispersion pipes.

According to still another aspect of the present invention, there is provided a non-transitory computer-readable recording medium storing a program causing a computer to perform: (a) supplying a first gas to a substrate accommodated in a process chamber through a first dispersion unit; and (b) supplying a second gas to the substrate through a second gas dispersion unit and a plurality of dispersion pipes connecting the process chamber and the second gas dispersion unit by penetrating an inside of the first gas dispersion unit, wherein an area of an inner surface of the second gas dispersion unit is smaller than a sum of an area of an inner surface of the first gas dispersion unit and areas of outer surfaces of the plurality of dispersion pipes.

### BRIEF DESCRIPTION OF THE DRAWINGS

FIG. 1 is a schematic configuration diagram of a substrate processing apparatus according to a first embodiment of the present invention.

FIG. 2A illustrates a shower head according to the first embodiment of the present invention, when viewed at a substrate.

FIG. 2B illustrates a first buffer space and a second buffer space of the shower head according to the first embodiment of the present invention.

FIG. 3 is a schematic configuration diagram of a gas supply system of the substrate processing apparatus according to the first embodiment of the present invention.

FIG. 4 is a schematic configuration diagram of a controller of the substrate processing apparatus according to the first embodiment of the present invention.

FIG. 5 is a flowchart of a substrate processing process according to the first embodiment of the present invention.

FIG. 6 is a schematic configuration diagram of a substrate processing apparatus according to a second embodiment of the present invention.

FIG. 7 is a schematic configuration diagram of a substrate processing system according to a third embodiment of the present invention.

### DETAILED DESCRIPTION

### First Embodiment

The first embodiment of the present invention will now be described with reference to the accompanying drawings.

### (1) Structure of Substrate Processing Apparatus

First, a substrate processing apparatus according to the first embodiment will be described below.

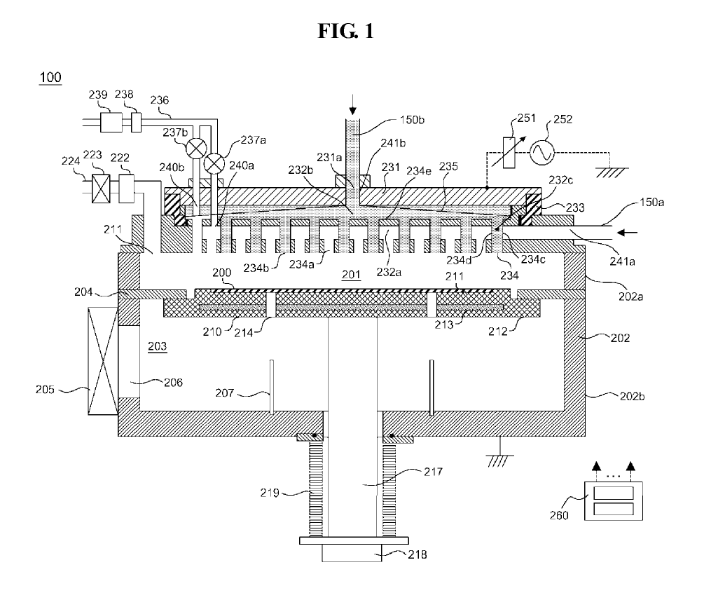

A substrate processing apparatus 100 according to the present embodiment will be described. The substrate processing apparatus 100 is a unit configured to form a high-k insulating film, and embodied as a single-wafer type substrate processing apparatus illustrated in FIG. 1. A process of manufacturing a semiconductor device as described above is performed by the substrate processing apparatus 100.

As illustrated in FIG. 1, the substrate processing apparatus 100 includes a process container 202. The process container 202 is configured, for example, as a flat air-tight container having a round cross-section. The process container 202 is formed of, for example, a metal material such as aluminum (Al) or stainless steel (SUS) or quartz (SiO2). In the process container 202, a process space (process chamber) 201 configured to process a wafer 200 such as a silicon wafer serving as a substrate, and a transfer space 203 are formed. The process container 202 includes an upper container 202a and a lower container 202b. A partition plate 204 is installed between the upper container 202a and the lower container 202b. A space surrounded by the upper container 202a and disposed above the partition plate 204 will be referred to as a ‘process space’ 201 (which may be also referred to as a process chamber). A space surrounded by the lower container 202b and disposed below the partition plate 204 will be referred to as a ‘transfer space’ 203.

At a side surface of the lower container 202b, a substrate loading exit 206 is installed adjacent to a gate valve 205. A wafer 200 is moved between transfer chambers (not shown) via the substrate loading exit 206. A plurality of lifting pins 207 are installed at a bottom surface of the lower container 202b. The lower container 202b is grounded.

In the process chamber 201, a substrate support 210 is installed to support wafers 200. The substrate support 210 includes a placement surface 211 on which the wafers 200 are placed, a substrate placement table 212 having the placement surface 211 thereon and a heater 213 serving as a heating unit. By installing the heating unit, a substrate may be heated to improve the quality of a film to be formed on the substrate. Through-holes 214 through which the plurality of lifting pins 207 pass may be installed at locations on the substrate placement table 212 corresponding to the plurality of lifting pins 207.

The substrate placement table 212 is supported by a shaft 217. The shaft 217 passes through a lower portion of the process container 202 and is connected to an elevating mechanism 218 outside the process container 202. By operating the elevating mechanism 218, the shaft 217 and the substrate placement table 212 may be moved up or down to move the wafer 200 placed on the substrate placement surface 211 upward or downward. The vicinity of a lower end portion of the shaft 217 is covered with bellows 219 and the inside of the process chamber 201 is maintained in an airtight state.

The substrate placement table 212 is moved down to move the substrate placement surface 211 to the position of the substrate loading exit 206 (a wafer transfer position) so as to transfer the wafer 200, and is moved up to a processing position (a wafer processing position) in the process chamber 201 as illustrated in FIG. 1 so as to process the wafer 200.

In detail, when the substrate placement table 212 is moved down to the wafer transfer position, upper end portions of the plurality of lifting pins 207 protrude from a top surface of substrate placement surface 211 to support the wafer 200 from below. When the substrate placement table 212 is moved up to the wafer processing position, the plurality of lifting pins 207 are buried from the top surface of the substrate placement surface 211, so that the wafer 200 may be supported from below by the substrate placement surface 211. Also, the plurality of lifting pins 207 are in direct contact with the wafer 200 and are thus preferably formed of, for example, a material such as quartz or alumina. Also, an elevating mechanism (not shown) may be installed on each of the plurality of lifting pins 207 so that the substrate placement table 212 and the plurality of lifting pins 207 may be moved relative to each other.

Exhaust System

An exhaust port 221 configured as a first exhaust unit to exhaust an atmosphere in the process chamber 201 is installed at a top surface of an inner wall of the process chamber 201 [upper container 202a]. An exhaust pipe 224 serving as a first exhaust pipe is connected to the exhaust port 221. A pressure adjusting unit 222 such as an auto pressure controller (APC) configured to control the inside of the process chamber 201 to have a predetermined pressure, and a vacuum pump 223 are sequentially connected in series to the exhaust pipe 224. The first exhaust unit (exhaust line) mainly includes the exhaust port 221, the exhaust pipe 224 and the pressure adjusting unit 222. The first exhaust unit may further include the vacuum pump 223.

A shower head exhaust port 240a serving as a second exhaust unit is installed on a top surface of an inner wall of a first buffer space 232a to exhaust an atmosphere in the first buffer space 232a. An exhaust pipe 236 serving as a second exhaust pipe is connected to the shower head exhaust port 240a. A valve 237a, a pressure adjusting unit 238 such as an APC configured to control the inside of the first buffer space 232a to have a predetermined pressure, and a vacuum pump 239 are sequentially connected in series to the exhaust pipe 236. The second exhaust unit (exhaust line) mainly includes the shower head exhaust port 240a, the valve 237a, the exhaust pipe 236 and the pressure adjusting unit 238. The second exhaust unit may further include the vacuum pump 239. The exhaust pipe 236 may be configured to be connected to the vacuum pump 223 without installing the vacuum pump 239.

A shower head exhaust port 240b serving as a third exhaust unit is installed on a top surface of an inner wall of a second buffer space 232b to exhaust an atmosphere in the second buffer space 232b. The exhaust pipe 236 is connected as a third exhaust pipe to the shower head exhaust port 240b. A valve 237b, the pressure adjusting unit 238 such as an APC configured to control the inside of the second buffer space 232b to have a predetermined pressure, and the vacuum pump 239 are sequentially connected in series to the exhaust pipe 236. The third exhaust unit (exhaust line) mainly includes the shower head exhaust port 240b, the valve 237b, the exhaust pipe 236 and the pressure adjusting unit 238. The third exhaust unit may further include the vacuum pump 223. A case in which the exhaust pipe 236, the pressure adjusting unit 238 and the vacuum pump 239 are shared between the third and second exhaust units is illustrated in FIG. 1. The exhaust pipe 236 may be configured to be connected to the vacuum pump 223 without installing the vacuum pump 239.

Gas Inlet Port

A first gas inlet port 241a is installed on a side wall of the upper container 202a via a first gas inlet pipe 150a to supply various gases into the process chamber 201. A second gas inlet port 241b is installed on a top surface (a ceiling surface) of a shower head 234 installed on an upper portion of the process chamber 201 via a second gas inlet pipe 150b to supply various gases into the process chamber 201. The structure of a gas supply system connected to the first gas inlet port 241a which is a first gas supply unit and the second gas inlet port 241b which is a second gas supply unit will be described below.

Gas Dispersion Unit

The shower head 234 serving as a gas dispersion unit is configured by the first buffer space (chamber) 232a, the second buffer space (chamber) 232b, first dispersion holes 234a and dispersion pipes 232c equipped with second dispersion holes 234b. The shower head 234 is installed between the second gas inlet port 241b and the process chamber 201. A first gas introduced via the first gas inlet port 241a is supplied to the first buffer space 232a (first gas dispersion unit) of the shower head 234. The second gas inlet port 241b is connected to a cover 231 of the shower head 234. A second gas introduced via the second gas inlet port 241b is supplied into the second buffer space 232b (second gas dispersion unit) of the shower head 234 via a hole 231a formed in the cover 231. The shower head 234 is formed of, for example, a material such as quartz, alumina, stainless steel or aluminum.

The cover 231 of the shower head 234 may be formed of a conductive material, and configured as an activation unit (excitation unit) for exciting a gas present in the first buffer space 232a, the second buffer space 232b or the process chamber 201. In this case, an insulating block 233 is installed between the cover 231 and the upper container 202a to insulate between the cover 231 and the upper container 202a. A matching unit 251 and a high-frequency power source 252 may be connected to an electrode (the cover 231) serving as an activation unit so as to supply electromagnetic waves (high-frequency power or microwaves).

The shower head 234 has a function of dispersing a gas, which is introduced via the first and second gas inlet ports 241a and 241b, between the first and second buffer spaces 232a and 232b and the process chamber 201. The first dispersion holes 234a and the dispersion pipes 232c equipped with the second dispersion holes 234b are installed on the shower head 234. The first gas is supplied into the process space 201 through the first dispersion holes 234a via the first buffer space 232a. The second gas is supplied into the process chamber 201 through the second dispersion holes 234b of the dispersion pipes 232c via the second buffer space 232b. The first dispersion holes 234a and the second dispersion holes 234b of the dispersion pipes 232c are disposed opposite the substrate placement surface 211.

A gas guide 235 may be installed to form a flow of the second gas supplied into the second buffer space 232b. The gas guide 235 has a cone shape having the hole 231a as a center thereof and having a diameter that increases in the direction of the diameter of the wafer 200. The diameter of a lower end of the gas guide 235 in a horizontal direction extends to an outer circumference of the substrate processing apparatus 100, compared to end portions of the first dispersion holes 234a and the dispersion pipes 232c.

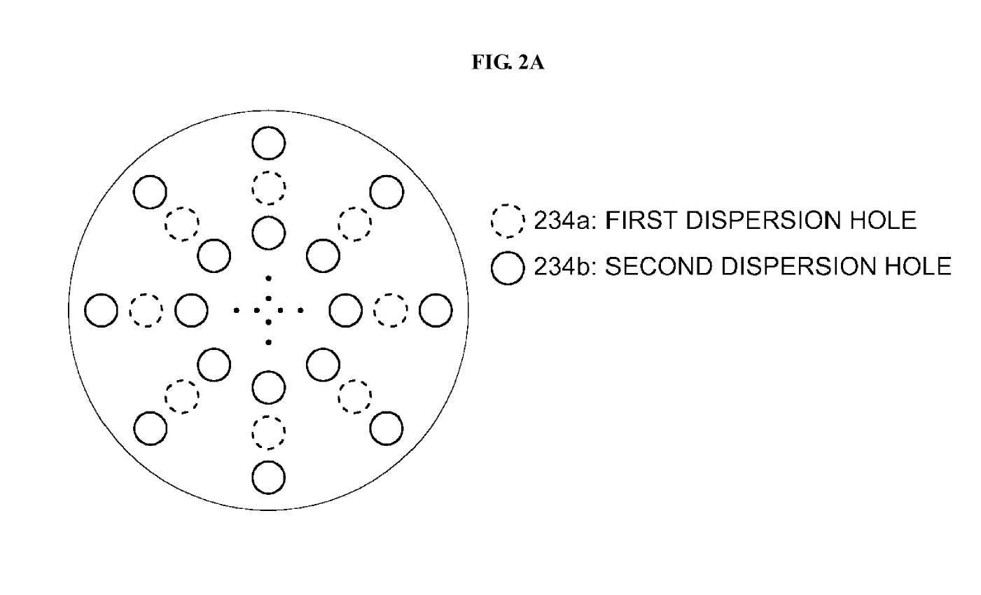

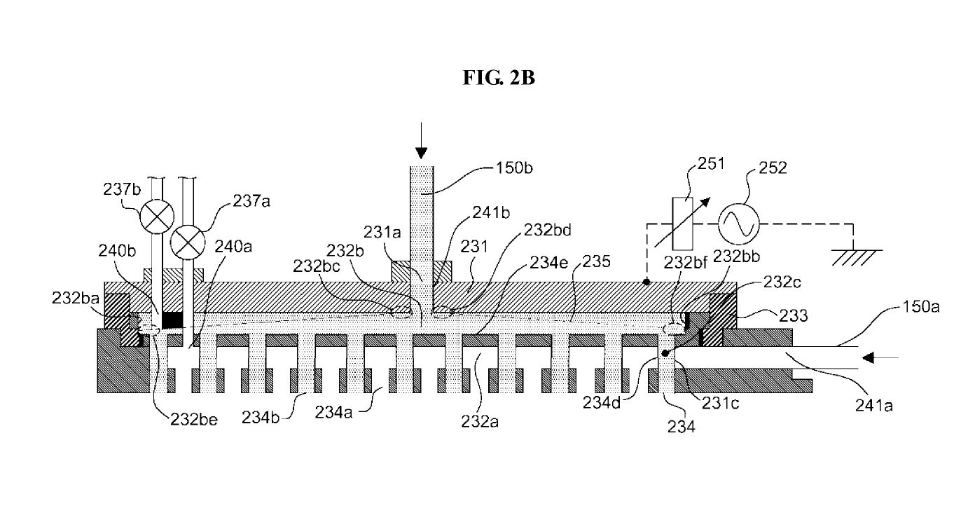

FIG. 2A illustrates the shower head 234 when viewed at the wafer 200. Here, for convenience of explanation, some dispersion holes 234a and 234b are omitted. As illustrated in FIG. 2A, the first gas dispersion holes 234a and the second gas dispersion holes 234b have the same diameter and are formed to be arranged at regular intervals. The diameters or positions of the first and second dispersion holes 234a and 234b may vary according to the type of substrate processing or the types of gases to be used.

Supply System

The first gas supply pipe 150a is connected to the first gas inlet port 241a which is the first gas supply unit connected to the upper container 202a. The second gas supply pipe 150b is connected to the second gas inlet port 241b which is the second gas supply unit connected to the cover 231 of the shower head 234. A source gas and a purge gas which will be described below are supplied through the first gas supply pipe 150a. A reactive gas and a purge gas which will be described below are supplied through the second gas supply pipe 150b.

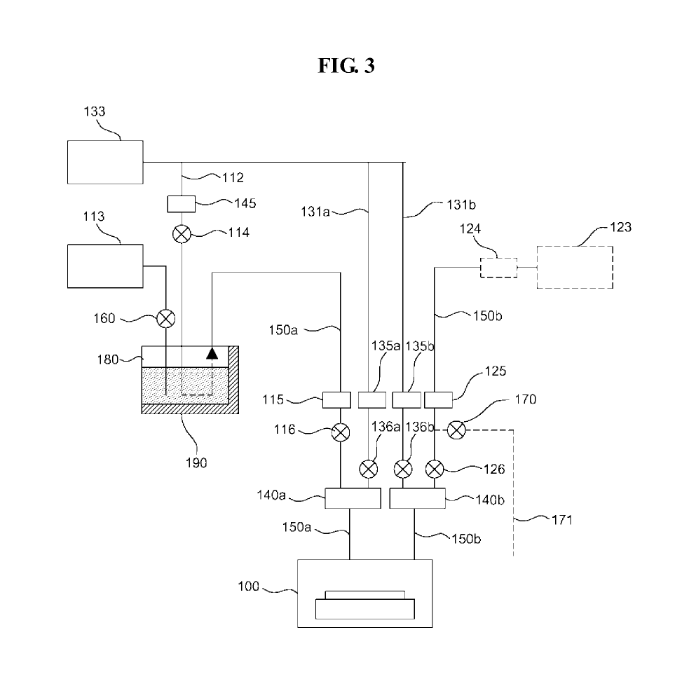

FIG. 3 is a schematic configuration diagram of the first gas supply unit, the second gas supply unit and a purge gas supply unit.

As illustrated in FIG. 3, a first gas supply pipe gathering unit 140a is connected to the first gas supply pipe 150a. A second gas supply pipe gathering unit 140b is connected to the second gas supply pipe 150b. The first gas supply pipe 150a and a purge gas supply unit 131a are connected to the first gas supply pipe gathering unit 140a. The second gas supply pipe 150b and a purge gas supply unit 131b are connected to the second gas supply pipe gathering unit 140b.

First Gas Supply Unit

A first gas source valve 160, a vaporizer 180, the first gas supply pipe 150a, a mass flow controller (MFC) 115, a gas valve 116 and a vaporizer residue measuring unit 190 are included in the first gas supply unit. The first gas supply unit may further include a first gas source 113. The vaporizer 180 is configured to vaporize a gas to bubble by supplying a carrier gas to a gas source that is in a liquid state.

The carrier gas is supplied via a gas supply pipe 112 connected to a purge gas supply source 133. A flow rate of the carrier gas is adjusted by an MFC 145 installed at the gas supply pipe 112, and the flow rate-adjusted carrier gas is supplied to the vaporizer 180 using a gas valve 114. The vaporizer residue measuring unit 190 is configured to measure the amount of a gas source, based on the weight, water level, etc. of a gas source in the vaporizer 180. The gas valve 114 is controlled to be opened or closed so as to control the amount of the gas source in the vaporizer 180 to be equal to a predetermined level, based on a result measured by the vaporizer residue measuring unit 190.

Second Gas Supply Unit

In the second gas supply unit, the second gas supply pipe 150b, an MFC 125 and a gas valve 126 are installed. A second gas source 123 may be further included in the second gas supply unit. Also, a remote plasma unit (RPU) 124 may be installed to activate the second gas. Also, a vent valve 170 and a vent pipe 171 may be installed to exhaust inert reactive gases accumulated in the second gas supply pipe 150b.

Purge Gas Supply Unit

In the purge gas supply unit, the gas supply pipes 112, 131a and 131b, the MFC 145, 135a and 135b, and the valves 114, 136a and 136b are installed. The purge gas supply source 133 may be further included in the purge gas supply unit.

Control Unit

As illustrated in FIG. 1, the substrate processing apparatus 100 includes a controller 260 configured to control operations of various elements of the substrate processing apparatus 100.

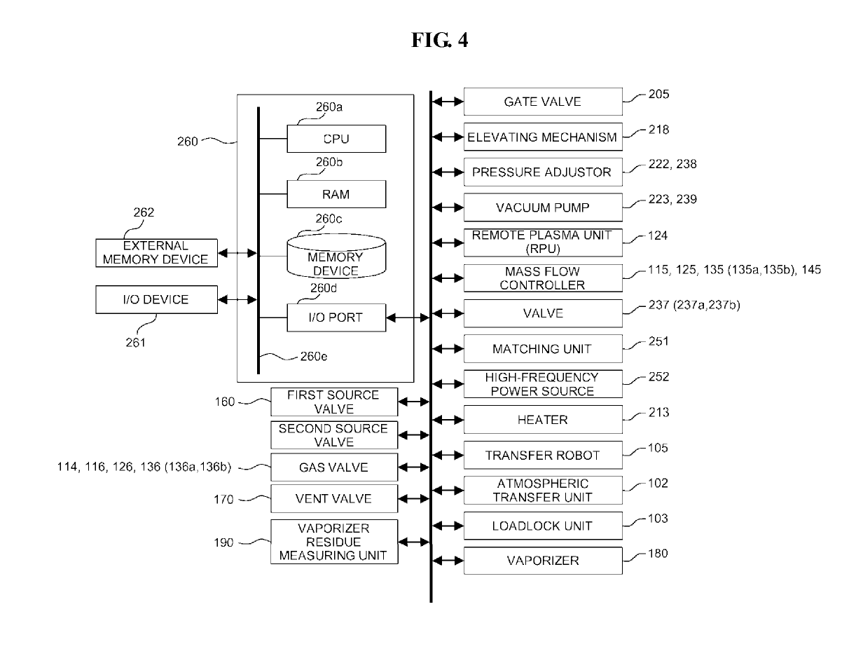

The controller 260 is schematically illustrated in FIG. 4. The controller 260 which is a control unit (control means) is configured as a computer including a central processing unit (CPU) 260a, a random access memory (RAM) 260b, a memory device 260c and an input/output (I/O) port 260d. The RAM 260b, the memory device 260c and the I/O port 260d are configured to exchange data with the CPU 260a via an internal bus 260e. An I/O device 261 configured, for example, as a touch panel or an external memory device 262 is connected to the controller 260.

The memory device 260c is configured, for example, as a flash memory, a hard disk drive (HDD) or the like. In the memory device 260c, a control program for controlling an operation of a substrate processing apparatus, a program recipe including an order or conditions of substrate processing which will be described below, etc. are stored to be readable. The process recipe is a combination of sequences of a substrate processing process which will be described below to obtain a desired result when the sequences are performed by the controller 260, and acts as a program. Hereinafter, the program recipe, the control program, etc. will also be collectively and simply referred to as a ‘program.’ When the term ‘program’ is used in the present disclosure, it should be understood as including only the program recipe, only the control program or both of the program recipe and the control program. The RAM 260b is configured as a memory area (a work area) in which a program or data read by the CPU 260a is temporarily stored.

The I/O port 260d is connected to the gate valve 205, the elevating mechanism 218, the heater 213, the pressure adjusting units 222 and 238, the vacuum pumps 223 and 239, the vaporizer 180, the vaporizer residue measuring unit 190, etc. The I/O port 260d may be also connected to the MFCs 115, 125 and 135 (135a and 135b) and 145, the valves 237 (237a and 237b), the gas valves 114, 116, 126 and 136 (136a and 136b), the first gas source valve 160, the vent valve 170, the RPU 124, the matching unit 251, the high-frequency power source 252, a transport robot 105, an atmospheric transfer chamber 102, a load lock unit 103, etc. which will be described below.

The CPU 260a is configured to read and execute the control program from the memory device 260c and to read the process recipe from the memory device 260c according to a manipulation command received via the I/O device 261. The CPU 260a is configured, based on the read process recipe, to control measuring of the amount of a residual gas by the vaporizer residue measuring unit 190; control opening/closing of the gate valve 205; control upward/downward movement of the elevating mechanism 218; control supplying of power to the heater 213; control adjustment of a pressure by the pressure adjusting units 222 and 238; control the vacuum pumps 223 and 239 to be ON/OFF; control activating of a gas by the RPU 124; control flow rates of gases by the MFCs 115, 125 and 135 (135a and 135b); control opening/closing of the valves 237 (237a and 237b), the gas valves 114, 116, 126 and 136 (136a and 136b), the first gas source valve 160 and the vent valve 170; control performing of power matching by the matching unit 251; control the high-frequency power source 252 to be ON/OFF, etc.

The controller 260 is not limited to a dedicated computer and may be configured as a general-purpose computer. For example, the controller 260 according to the present embodiment may be configured by preparing the external memory device 262 storing a program as described above, e.g., a magnetic disk (a magnetic tape, a flexible disk, a hard disk, etc.), an optical disc (a compact disc (CD), a digital versatile disc (DVD), etc.), a magneto-optical (MO) disc or a semiconductor memory (a Universal Serial Bus (USB) memory, a memory card, etc.), and then installing the program in a general-purpose computer using the external memory device 262. Also, means for supplying a program to a computer are not limited to using the external memory device 262. For example, a program may be supplied to a computer using communication means, e.g., the Internet or an exclusive line, without using the external memory device 262. The memory device 260c or the external memory device 262 may be configured as a non-transitory computer-readable recording medium. Hereinafter, the memory device 260c and the external memory device 262 may also be collectively and simply referred to as a ‘recording medium.’ When the term ‘recording medium’ is used in the present disclosure, it may be understood as including only the memory device 260c, only the external memory device 262 or both the memory device 260c and the external memory device 262.

### (2) Substrate Processing Process

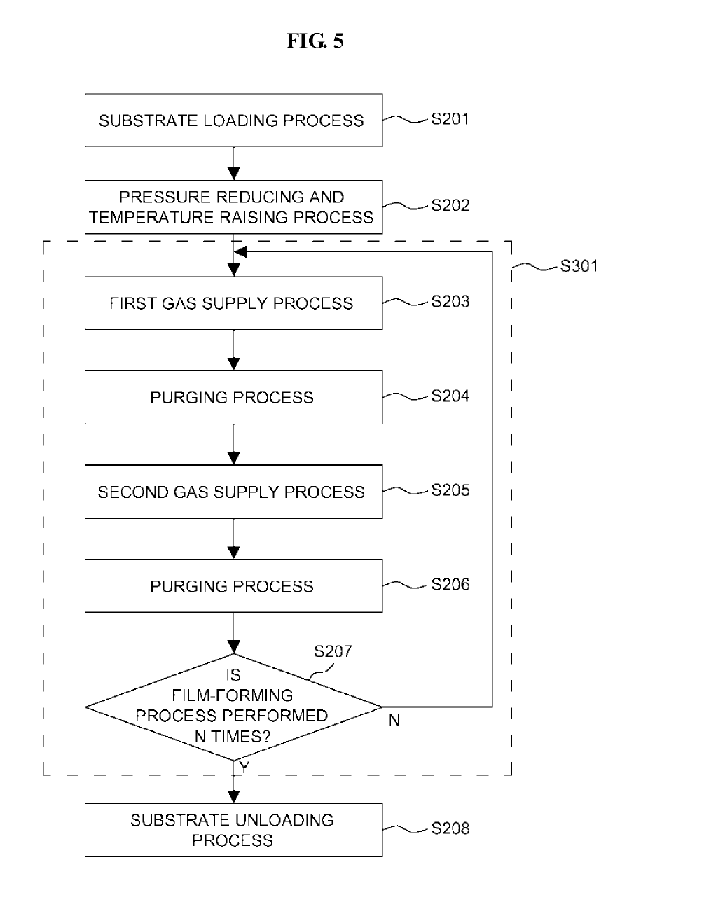

Next, a sequence of forming a conductive film, e.g., a metal-containing film such as a titanium nitride (TiN) film which is a transition metal nitride film, on a substrate using a process furnace of a substrate processing apparatus as described above will be described with reference to FIG. 5 below, as a process included in a process of manufacturing a semiconductor device. In the following description, operations of various elements of the substrate processing apparatus 100 are controlled by the controller 260.

When the term ‘wafer’ is used in the present disclosure, it should be understood as either the wafer itself or both the wafer and a stacked structure (assembly) including a layer/film formed on the wafer (i.e., the wafer and the layer/film formed thereon may also be collectively referred to as the ‘wafer’). Also, when the expression ‘surface of the wafer’ is used in the present disclosure, it should be understood as either a surface (exposed surface) of the wafer itself or a surface of a layer/film formed on the wafer, i.e., an uppermost surface of the wafer as a stacked structure.

Thus, in the present disclosure, the expression “specific gas is supplied onto a wafer” should be understood to mean that the specific gas is directly supplied onto a surface (exposed surface) of the wafer or that the specific gas is supplied onto a surface of a layer/film formed on the wafer, i.e., on the uppermost surface of the wafer as a stacked structure. Otherwise, the above expression may be understood to mean that a layer or film is formed on a layer/film formed on the wafer, i.e., the uppermost surface of the wafer as a stacked structure.

Also, in the present disclosure, the term ‘substrate’ has the same meaning as the term ‘wafer.’ Thus, the term ‘wafer’ may be used interchangeably with the term ‘substrate.’

A substrate processing process will now be described.

Substrate Loading Process (Operation S201)

In order to form a film, first, a wafer 200 is loaded into the process chamber 201. In detail, the substrate support 210 is moved down by the elevating mechanism 218 such that the plurality of lifting pins 207 protrude from the through-holes 214 to the top surface of the substrate support 210. Also, the inside of the process chamber 201 is regulated to have a predetermined pressure and the gate valve 205 is opened to place the wafer 200 on the plurality of lifting pins 207. After the wafer 200 is placed on the plurality of lifting pins 207, the substrate support 210 is moved up to a predetermined position by the elevating mechanism 218 so as to move the wafer 200 from the plurality of lifting pins 207 to the substrate support 210.

Pressure Reducing and Temperature Raising Process (Operation S202)

Then, the inside of the process chamber 201 is exhausted via the exhaust pipe 224 to have a predetermined pressure (degree of vacuum). In this case, the degree of openness of the pressure adjusting unit 222 which is an APC valve is feedback-controlled based on a pressure measured by a pressure sensor (not shown). Also, the amount of electric power to be supplied to the heater 213 is feedback-controlled such that the inside of the process chamber 201 has a predetermined temperature, based on a temperature detected by a temperature sensor (not shown). In detail, the substrate support 210 is heated beforehand by the heater 213, and the supply of the electric power to the heater 213 is continuously feedback-controlled for a predetermined time after the temperature of the wafer 200 or the substrate support 210 is maintained constant. In this case, when moisture remains in the process chamber 201 or degassing occurs in an element present in the process chamber 201, vacuum exhaustion may be performed or the degassing may be canceled by purging the side of the process chamber 201 by supplying N₂ gas thereto. Therefore, a preparation for a film-forming process S301 is completed. In order to exhaust the inside of the process chamber 201 to have the predetermined pressure, vacuum exhaustion may be performed once or to have a degree of vacuum that can be achieved.

Film-Forming Process (Operation S301)

Next, a method of forming a TiN film on the wafer 200 will be described. The film-forming process (operation S301) will be described in detail with reference to FIG. 5 below.

After the wafer 200 is placed on the substrate support 210 and an atmosphere in the process chamber 201 is stabilized, operations S203 to S207 illustrated in FIG. 5 are performed.

First Gas Supply Process (Operation S203)

In the first gas supply process (S203), titanium tetrachloride (TiCl₄) gas is supplied as a first gas (source gas) into the process chamber 201 through a first gas supply system. In detail, the gas source valve 160 is opened to supply the TiCl₄ gas to the vaporizer 180. In this case, the gas valve 114 is opened, and a carrier gas having a flow rate adjusted to a predetermined level by the MFC 145 is supplied to the vaporizer 180 so as to cause TiCl₄ to bubble, thereby changing the TiCl₄ into a gaseous state. The changing of the TiCl₄ into the gaseous state gas may be performed before the substrate loading process (operation S201) is performed. The flow rate of the TiCl₄ gas that is in the gaseous state is adjusted by the MFC 115, and the flow rate-adjusted TiCl₄ gas is supplied to the substrate processing apparatus 100. The flow rate-adjusted TiCl₄ gas is supplied into the pressure-reduced process chamber 201 via the first buffer space 232a and the first dispersion holes 234a of the shower head 234. Also, the inside of the process chamber 201 is continuously exhausted by the exhaust system to control the inside of the process chamber 201 to have a predetermined pressure range (a first pressure range). In this case, the TiCl₄ gas supplied to the wafer 200 is supplied into the process chamber 201 at a predetermined pressure (a first pressure), e.g., 100 Pa to 20,000 Pa. The TiCl₄ gas is supplied to the wafer 200 as described above. When the TiCl₄ gas is supplied to the wafer 200, a titanium (Ti)-containing layer is formed on the wafer 200.

Purging Process (Operation S204)

After the titanium-containing layer is formed on the wafer 200, the gas valve 116 of the first gas supply pipe 150a is closed to stop the supply of the TiCl₄ gas. By stopping the supply of the TiCl₄ gas serving as the source gas, the purging process (operation S204) is performed to exhaust the source gas remaining in the process chamber 201 or the first buffer space 232a via the first exhaust unit.

The purging process (operation S204) may be set to discharge a gas not only by simply exhausting (vacuum-sucking) the gas but also by supplying an inert gas to push out a residual gas. Otherwise, the vacuum-sucking of the gas and the supplying of the inert gas may be performed in combination. Otherwise, the vacuum-sucking of the gas and the supplying of the inert gas may be alternately performed.

In this case, the valve 237a of the exhaust pipe 236 may be opened to exhaust a gas present in the first buffer space 232a through the vacuum pump 239 via the exhaust pipe 236. In this case, the vacuum pump 239 is operated beforehand, and continuously operated at least until the substrate processing process is completed. During the exhausting, pressures (exhaust conductances) in the exhaust pipe 236 and the first buffer space 232a are controlled using the pressure adjusting unit 238 such as an APC valve. The controlling of the exhaust conductance may be performed to control the pressure adjusting unit 238 and the vacuum pump 239 so as to control an exhaust conductance of a first exhaust system in the first buffer space 232a to be higher than an exhaust conductance in the vacuum pump 223 via the process chamber 201. By controlling the exhaust conductances as described above, a gas flow is formed from the first gas inlet port 241a corresponding to one end portion of the first buffer space 232a to the shower head exhaust port 240a corresponding to another end portion of the first buffer space 232a. Thus, a gas attached to a wall of the first buffer space 232a or a gas floating in the first buffer space 232a may be prevented from flowing into the process chamber 201 and may be exhausted via the first exhaust system. Also, a pressure in the first buffer space 232a and a pressure (exhaust conductance) in the process chamber 201 may be adjusted to suppress a gas from flowing backward from the process chamber 201 into the first buffer space 232a.

Also, in the purging process (operation S204), the vacuum pump 223 is continuously operated to exhaust a gas present in the process space 201 through the vacuum pump 223. Also, the pressure adjusting unit 222 may be controlled to control an exhaust conductance from the process chamber 201 to the vacuum pump 223 to be higher than an exhaust conductance to the first buffer space 232a. Thus, the flow of a gas toward a second exhaust system via the process chamber 201 is formed to exhaust a gas remaining in the process chamber 201. Here, the gas valve 136a may be opened and the MFC 135a may be controlled to supply an inert gas. Thus, the inert gas may be reliably supplied to the wafer 200, thereby increasing the efficiency of removing a residual gas from the wafer 200.

After a predetermined time elapses, the valve 136a is closed to stop the supply of the inert gas, and at the same time, the valve 237a is closed to block a space between the first buffer space 232a and the vacuum pump 239.

More preferably, after the predetermined time elapses, the valve 237a is closed while operating the vacuum pump 223. Thus, the flow of the gas toward the second exhaust system via the process chamber 201 is not influenced by the first exhaust system. Thus, the inert gas may be more reliably supplied to the wafer 200, thereby greatly increasing the efficiency of removing a residual gas from the wafer 200.

The purging of the process chamber 201 should be understood to include not only discharging a gas by simply vacuum-sucking the gas but also discharging a gas by supplying an inert gas to push out the gas. Thus, the purging process (operation S204) may be set to push a residual gas out of the first buffer space 232a by supplying an inert gas into the first buffer space 232a. Otherwise, the vacuum-sucking of the gas and the supplying of the inert gas may be performed in combination. Otherwise, the vacuum-sucking of the gas and the supplying of the inert gas may be alternately performed.

In this case, the flow rate of N₂ gas to be supplied into the process chamber 201 need not be high. For example, the inside of the process chamber 201 may be purged without causing a negative influence to occur in a subsequent operation by supplying an amount of the N₂ gas corresponding to the capacity of the process chamber 201. When the inside of the process chamber 201 is not completely purged, a purge time may be reduced to improve the throughput. Furthermore, the consumption of the N₂ gas may be reduced to a necessary minimum level.

In this case, the heater 213 is set to be maintained at a temperature that is within a range of 200° C. to 750° C., preferably, a range of 300° C. to 600° C., and more preferably, a range of 300° C. to 550° C., similar to the temperature of the heater 213 when the source gas is supplied to the wafer 200. A supply flow rate of the N₂ gas to be supplied as a purge gas through each of various inert gas supply systems is set to be within, for example, a range of 100 sccm to 20,000 sccm. A rare gas such as argon (Ar) gas, helium (He) gas, neon (Ne) gas, xenon (Xe) gas, etc. may be used as the purge gas, in addition to the N₂ gas.

Second Gas Supply Process (Operation S205)

After the purging process (operation S204) using the first gas, the gas valve 126 is opened to supply ammonia gas (NH₃) as a second gas (a reactive gas) into the process chamber 201 via the gas inlet port 241b, the second buffer space 232b and the dispersion pipes 232c equipped with the second dispersion holes 234b. Since the second gas (reactive gas) is supplied into the process chamber 201 via the second buffer space 232b and the dispersion pipes 232c, the second gas (reactive gas) may be uniformly supplied to the wafer 200. Thus, a desired film may be formed to a uniform thickness. Also, when the second gas is supplied, the second gas may be activated via the RPU 124 serving as an activation unit (excitation unit), and supplied into the process chamber 201.

In this case, the NH₃ gas is adjusted to have a predetermined flow rate by the MFC 125. Also, the supply flow rate of the NH₃ gas is, for example, in a range of 100 sccm to 10,000 sccm. By appropriately controlling the pressure adjusting unit 238, the inside of the second buffer space 232b has a pressure that is within a predetermined pressure. When the NH₃ gas flows in the RPU 124, the RPU 124 is controlled to be ‘ON’ (to be in a powered ‘on’ state) to activate (excite) the NH₃ gas.

When the NH₃ gas is supplied to a titanium-containing layer formed on the wafer 200, the titanium-containing layer is modified. For example, a modification layer containing element of titanium is formed. Also, more modification layers may be formed by installing the RPU 124 and supplying the activated NH₃ gas to the wafer 200.

The modification layer is formed to have, for example, a predetermined thickness, a predetermined distribution and a penetration depth of a predetermined nitrogen component, etc. with respect to the titanium-containing layer, based on a pressure in the process chamber 201, the flow rate of the NH₃ gas, the temperature of the wafer 200 and a power supply state of the RPU 124.

After a predetermined time elapses, the gas valve 126 is closed to stop the supply of the NH₃ gas.

Purging Process (Operation S206)

After the supply of the NH₃ gas is stopped, the purging process (operation S206) is performed by exhausting through the first exhaust unit the source gas present in the process chamber 201 or the second buffer space 232b.

The purging process (operation S206) may be set to discharge a gas not only by simply exhausting (vacuum-sucking) the gas but also by supplying an inert gas to push out a residual gas. Otherwise, the vacuum-sucking of the gas and the supplying of the inert gas may be performed in combination. Otherwise, the vacuum-sucking of the gas and the supplying of the inert gas may be alternately performed.

Also, the valve 237b may be opened to exhaust a gas present in the second buffer space 232b through the vacuum pump 239 via the exhaust pipe 236. During the exhausting, the pressure adjusting unit 238 controls pressures (exhaust conductances) in the exhaust pipe 236 and the second buffer space 232b. The controlling of the exhaust conductance may be performed by controlling the pressure adjusting unit 238 and the vacuum pump 239 so as to control an exhaust conductance of the first exhaust system in the second buffer space 232b to be higher than an exhaust conductance in the vacuum pump 223 via the process chamber 201. By controlling the exhaust conductances as described above, a gas flow is formed from a center of the second buffer space 232b toward the shower head exhaust port 240b. Thus, a gas attached to a wall of the second buffer space 232b or a gas floating in the second buffer space 232b may be prevented from flowing into the process chamber 201 and may be exhausted through a third exhaust system. Also, a pressure in the second buffer space 232b and a pressure (exhaust conductance) in the process chamber 201 may be adjusted to suppress a gas from flowing backward from the process chamber 201 into the second buffer space 232b.

Also, in the purging process (operation S206), the vacuum pump 223 is continuously operated to exhaust a gas present in the process space 201 through the vacuum pump 223. Also, the pressure adjusting unit 222 may be controlled to control an exhaust conductance from the process chamber 201 to the vacuum pump 223 to be higher than an exhaust conductance to the second buffer space 232b. Thus, the flow of a gas toward the third exhaust system via the process chamber 201 is formed to exhaust a gas remaining in the process chamber 201. Here, the gas valve 136b may be opened and the MFC 135b may be controlled to supply an inert gas. Thus, the inert gas may be reliably supplied to the wafer 200, thereby increasing the efficiency of removing a residual gas from the wafer 200.

After a predetermined time elapses, the valve 136b is closed to stop the supply of the inert gas, and at the same time, the valve 237b is closed to block a space between the second buffer space 232b and the vacuum pump 239.

More preferably, after the predetermined time elapses, the valve 237b is closed while operating the vacuum pump 223. Thus, the flow of the gas toward the third exhaust system via the process chamber 201 is not influenced by the first exhaust system. Thus, the inert gas may be more reliably supplied to the wafer 200, thereby greatly increasing the efficiency of removing a residual gas from the wafer 200.

The purging of the process chamber 201 should be understood to include not only discharging a gas by simply vacuum-sucking the gas but also discharging a gas by supplying an inert gas to push out the gas. Thus, the purging process (operation S206) may be set to push a residual gas out of the second buffer space 232b by supplying an inert gas into the second buffer space 232b. Otherwise, the vacuum-sucking of the gas and the supplying of the inert gas may be performed in combination. Otherwise, the vacuum-sucking of the gas and the supplying of the inert gas may be alternately performed.

Also, in this case, the flow rate of N₂ gas to be supplied into the process chamber 201 need not be high. For example, the inside of the process chamber 201 may be purged without causing a negative influence to occur in a subsequent operation by supplying an amount of the N₂ gas corresponding to the capacity of the process chamber 201. When the inside of the process chamber 201 is not completely purged, a purge time may be reduced to improve the throughput. Furthermore, the consumption of the N₂ gas may be reduced to a necessary minimum level.

In this case, the temperature of the heater 213 is set to be within a range of 200° C. to 750° C., preferably, a range of 300° C. to 600° C., and more preferably, a range of 300° C. to 550° C., similar to the temperature of the heater 213 when the source gas is supplied to the wafer 200. A supply flow rate of the N₂ gas to be supplied as a purge gas through each of various inert gas supply systems is set to be within, for example, a range of 100 sccm to 20,000 sccm. A rare gas such as argon (Ar) gas, helium (He) gas, neon (Ne) gas, xenon (Xe) gas, etc. may be used as the purge gas, in addition to the N₂ gas.

Determination Process (Operation S207)

After the purging process (operation S206) is ended, the controller 260 determines whether the film-forming process (S301) (including operations S203 to S206) is performed in a predetermined number of cycles (n times) (operation S207)]. That is, the controller 260 determines whether a film is formed to a desired thickness on the wafer 200. By performing one cycle including operations S203 to S206 at least once (operation S207), a conductive film including elements of titanium and nitrogen, i.e., a TiN film, may be formed on the wafer 200 to a predetermined thickness. The above cycle is preferably performed a plurality of times. Thus, a TiN film is formed on the wafer 200 to the predetermined thickness.

When it is determined in operation S207 that the cycle is not performed a predetermined number of times, i.e., when it is determined ‘No’ in operation S207, the cycle including operations S203 to S206 is repeatedly performed. When it is determined in operation S207 that the cycle is performed the predetermined number of times, i.e., when it is determined ‘Yes’ in operation S207, the film-forming process (operation S301) is ended and a substrate unloading process (S208) is performed.

Substrate Unloading Process (Operation S208)

After the film-forming process (operation S301) is ended, the substrate support 210 is moved down by the elevating mechanism 218 and thus the plurality of lifting pins 207 protrude from the through-holes 214 to the top surface of the substrate support 210. Also, the inside of the process chamber 201 is regulated to have a predetermined pressure and the gate valve 205 is opened to unload the wafer 200 from the plurality of lifting pins 207 to the outside of the gate valve 205.

In the first gas supply process (S203) or the second gas supply process (S205) as described above, an inert gas may be supplied to the second buffer space 232b which is a second gas dispersion unit when the first gas is supplied and may be supplied to the first buffer space 232a which is a first gas dispersion unit when the second gas is supplied, thereby preventing the first and second gases from respectively flowing backward to the second and first buffer spaces 232b and 232a.

When a titanium nitride (TiN) film is formed using a titanium-containing gas as the first gas and a nitrogen-containing gas as the second gas, an unintended reaction may occur and prevent a film having desired characteristics from being formed due to the following reasons. One of the reasons is that NH₄Cl is generated as a byproduct and hinders a desired reaction. Since NH₄Cl is generated when TiCl₄ which is a residual titanium-containing gas and NH₃ which is a nitrogen-containing gas react with each other, it is important to reduce a residue of NH₃. The other reason is that the second gas (NH₃) remaining in or adsorbed onto a member present in the process chamber 201 is separated from the member and supplied to the wafer 200 when the first gas or another gas is supplied, thereby causing an unintended reaction to occur. Here, the unintended reaction is, for example, a reaction occurring in a space (a gas-phase reaction). The characteristics of a semiconductor device are degraded due to these reasons.

Next, the relationship between the first buffer space 232a which is a first gas dispersion unit and the second buffer space 232b which is a second gas dispersion unit will be described below. The plurality of first dispersion holes 234a are formed in the process space 201 from the first buffer space 232a. The plurality of dispersion pipes 232c extend from the second buffer space 232b to the process space 201. The second buffer space 232b is installed above the first buffer space 232a. Thus, the process space 201 extends such that the dispersion pipes 232c of the second buffer space 232b pass through the inside of the first buffer space 232a as illustrated in FIG. 1.

Since the dispersion pipes 232c of the second buffer space 232b pass through the inside of the first buffer space 232a, outer surfaces 234c and 234d of the dispersion pipes 232c are exposed in the first buffer space 232a. The sum of an area of inner surfaces of the first buffer space 232a and areas of the outer surfaces 234c and 234d of the dispersion pipes 232c is greater than the sum of areas of inner surfaces of the second buffer space 232b. Hereinafter, the sum of the areas of the inner surfaces of the first buffer space 232a and the areas of the outer surfaces 234c and 234d of the dispersion pipes 232c will be referred to as simply ‘the area of the inner surfaces of the first buffer space 232a. The areas of the outer surfaces 234c and 234d of the dispersion pipes 232c in the first buffer space 232a may be considered as a perpendicular area with respect to the wafer 200. Also, areas of side surfaces 232ba and 232bb of the second buffer space 232b may be considered as a perpendicular area with respect to the wafer 200 in the second buffer space 232b). Since the dispersion pipes 232c are disposed in the first buffer space 232a, the areas of the outer surfaces 234c and 234d of the dispersion pipes 232c are greater than the perpendicular area with respect to the wafer 200 in the second buffer space 232b as illustrated in FIG. 2B.

Molecules of gases supplied to the first and second buffer spaces 232a and 232b may be adsorbed onto the inner walls of the first and second buffer spaces 232a and 232b. The molecules of the gases are removed in the purging processes S204 and S206. The inventors of the present application, however, found that the molecules of some gases remain on the inner walls of these buffer spaces and are separated from the inner walls in a different operation, thereby causing an unintended reaction to occur. For example, when a TiN film is formed by alternately supplying TiCl₄ and NH₃ as described above, molecules of NH₃ may be separated from the inner walls of these buffer spaces and supplied into the process space 201 when TiCl₄ is supplied and thus a gas-phase reaction may occur between TiCl₄ and NH₃ in the process space 201 to form an unintended film. Also, NH₄Cl which is a byproduct may be generated and prevent a desired film from being formed.

Also, the outer surface 234c of the dispersion pipes 232c in the first buffer space 232a, which is located adjacent to the first gas inlet port 241a, is disposed opposite a supplied gas (a direction in which a gas supplied through the gas supply pipe 150a flows). Thus, molecules of a gas adsorbed onto the outer surface 234c are likely to be in contact with a purge gas and may be thus easily removed when a purging operation is performed. In contrast, the outer surface 234d of the dispersion pipes 232c in the first buffer space 232a, which is disposed opposite the first gas inlet port 241a, is disposed opposite a supplied gas (i.e., disposed in the direction in which a gas supplied through the gas supply pipe 150a flows). Thus, in a purging operation, a purge gas was difficult to be supplied to the outer surface 234d and molecules of a gas adsorbed thereon were not removed and thus remained on the outer surface 234d. The vicinity of the outer surface 234d may be considered as a position which molecules of a gas hardly penetrate. Also, the positions of the outer surfaces 234c and 234d may vary according to the position of a gas pipe connected to the first buffer space 232a, i.e., the position of the first gas inlet port 241a. For example, when a gas is supplied through a center of the first buffer space 232a, the outer surface 234c may be formed in the direction of the center of the first buffer space 232a and the outer surface 234d may be formed in the direction of an outer circumference of the first buffer space 232a. Also, the first dispersion holes 234a) and the second dispersion holes 234b of the dispersion pipes 232c are circular holes having the same diameter.

A portion 234e of the second buffer space 232b is disposed opposite a direction in which a gas supplied through the gas supply pipe 150b flows. Molecules of a gas adsorbed onto the portion 234e may be easily removed when the molecules of the gas are in contact with a purge gas during a purging process. Referring to FIG. 2B, portions 232bc, 232bd, 232be and 232bf of surfaces of the gas guide 235 of the second buffer space 232b may be considered as points which molecules of gases hardly penetrate. That is, the central portions 232bc and 232bd and edge portions 232be and 232bf of the gas guide 235 may be considered as points which molecules of gases hardly penetrate. Referring to FIG. 2B, in the second buffer space 232b, the areas of the central portions 232bc and 232bd and the edge portions 232be and 232bf of the gas guide 235 are less than an area of the outer surface 234d disposed opposite the first gas inlet port 241a among the outer surfaces of the dispersion pipes 232c in the first buffer space 232a. The central portions 232bc and 232bd of the gas guide 235 may be referred to as a surface of a first retention region, and the outer surface 234d of the dispersion pipes 232c may be referred to as a surface of a second retention region. The term ‘retention region’ should be understood as a region where molecules of gases hardly penetrate.

The inventors of the present application found that unintended reactions were reduced by changing a gas supply position according to the characteristics (adsorbabilities, vapor pressures, etc.) of a source gas and a reactive gas. For example, when TiCl₄ and NH₃ are supplied, unintended reactions (formation of an unintended film, generation of NH₄Cl, etc.) may be reduced by supplying NH₃, which is more likely to be attached to inner walls of a buffer space than TiCl₄, into a buffer space with small inner surfaces and supplying TiCl₄ into a buffer space with large inner surfaces.

Thus, in the present embodiment, TiCl₄ is supplied as the first gas into the first buffer space 232a with large inner surfaces of a buffer chamber, and NH₃ is supplied as the second gas into the second buffer space 232b with small inner surfaces of the buffer chamber. Here, an amount of TiCl₄ (the first gas) adsorbed per unit area is less than that of NH₃ (the second gas) adsorbed per unit area. Also, the first gas may be more easily separated than the second gas (in other words, the second gas may be more difficult to be separated than the first gas) after the first and second gases are adsorbed.

Although the source gas and the reactive gas are respectively supplied into the first buffer space 232a with large-area inner surfaces and the second buffer space 232b with small-area inner surfaces in the above embodiment, the positions to which the source gas and the reactive gas are supplied may be switched to each other, based on the characteristics (adsorbabilities, vapor pressures, etc.) of the source gas and the reactive gas.

Desired effects may be also achieved by supplying a gas that is less adsorbed per unit area into a buffer space in which an area of a portion from which the molecules of the gas are easily removed<an area of a portion which the molecules of the gas hardly penetrate, and supplying a gas that is more adsorbed per unit area into a buffer space in which an area of a portion from which the molecules of the gas are easily removed>an area of a portion which the molecules of the gas hardly penetrate.

Effects of the Present Embodiment

According to the present embodiment, the following one or more effects may be achieved.

(a) In an apparatus configured to form a film by supplying two or more types of gases, an unintended reaction may be suppressed by supplying a gas that is easy to be adsorbed to a buffer space, the area of inner surfaces of which is small and supplying a gas that is difficult to be adsorbed to a buffer space, the area of inner surfaces of which is large.

(b) A gas may be suppressed from being adsorbed in a buffer space by setting an area of inner surfaces of a second buffer space to which a gas that is easy to be adsorbed is supplied to be less than an area of inner surfaces of a first buffer space to which a gas that is difficult to be adsorbed is supplied.

(c) The amount of NH₄Cl to be generated may be reduced or an unintended reaction may be suppressed by reducing a residue of NH₃.

### Second Embodiment

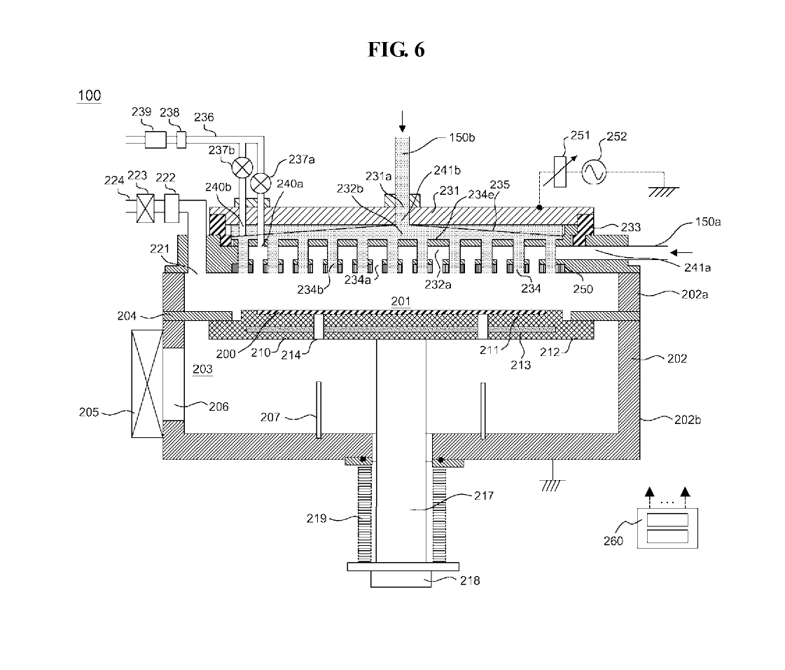

FIG. 6 illustrates a second embodiment of the present invention. In the present embodiment, a thermal insulation unit 250 is disposed between a wafer 200 and a first buffer space 232a which is a first gas dispersion unit, compared to the first embodiment.

Although a first dispersion hole 234a and dispersion pipes 232c are installed in a shower head 234 to uniformly supply a gas to the wafer 200, the viscosity of the gas changes according to the position (temperature) of the shower head 234 when the temperature of the shower head 234 is not uniform in the direction of the diameter of the wafer 200. Thus, the density or amount of a gas to be supplied to the wafer 200 varies according to the position of the shower head 234. This is because the shower head 234 is heated by, for example, heat from a substrate placement table 212 (susceptor) and the heat is exposed from an outer circumference of the shower head 234 to an upper process container 202a. Thus, in the present embodiment, the thermal insulation unit 250 is installed between the wafer 200 and the first buffer space 232a which is the first gas dispersion unit. This structure blocks heat from being supplied to the shower head 234 from the substrate placement table 212 so as to make the temperature of the shower head 234 constant. Also, when the thermal insulation unit 250 is installed, the temperature of the substrate placement table 212 or the amount of electric power to be supplied to the heater 213 may be maintained constant even when they are exposed to heat. Although the thermal insulation unit 250 is a vacuum layer, the thermal insulation unit 250 is not limited to the vacuum layer and may be formed of a material or a structure that hinders conduction of heat. For example, the thermal insulation unit 250 may be ceramics or aerogel containing one of silicon, aluminum and carbon, or the like.

### Third Embodiment

Although the second embodiment has been described above in detail, the present invention is not limited thereto and may be embodied in many different forms without departing from the scope of the invention.

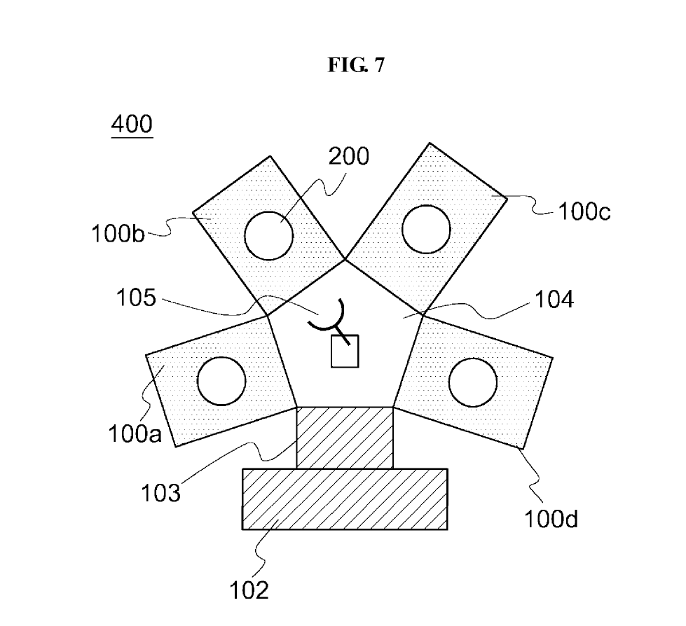

FIG. 7 illustrates a substrate processing system according to a third embodiment of the present invention.

As illustrated in FIG. 7, a substrate processing system 400 includes four substrate processing apparatuses 100a, 100b, 100c and 100d in a vacuum transfer chamber 104. The same type of processing is performed in the substrate processing apparatuses 100a, 100b, 100c and 100d. Wafers 200 are sequentially transferred to the substrate processing apparatuses 100a, 100b, 100c and 100d by a vacuum transport robot 105 installed in the vacuum transfer chamber 104. The wafers 200 are loaded into the vacuum transfer chamber 104 from an atmospheric transfer chamber 102 via a load lock unit 103. Although FIG. 7 illustrates a case in which the four substrate processing apparatuses 100a, 100b, 100c and 100d are installed, the present invention is not limited thereto and two or more substrate processing apparatuses may be installed. For example, five or more substrate processing apparatuses, e.g., eight substrate processing apparatuses, may be installed.

Although a process of manufacturing a semiconductor device has been described above, the present invention is also applicable to, for example, a process of manufacturing a liquid crystal device, a plasma treatment performed on a ceramic substrate, etc.

Also, although a method of forming a film by alternately supplying a source gas and a reactive gas has been described above, the present invention is also applicable to other methods, provided that the degree of a gas-phase reaction occurring in the source gas and the reactive gas or the amount of byproducts generated are within an allowed range. For example, a timing at which the source gas is supplied and a timing at which the reactive gas is supplied may be set to overlap each other.

Also, although a method of forming a film has been described above, the preset invention is also applicable to other treatments, e.g., a diffusion treatment, oxidation, nitridation, oxynitridation, reduction, a redox treatment, an etching treatment, a thermal treatment, etc.

Also, although a case in which a titanium nitride film is formed using a titanium-containing gas (TiCl₄) gas as a source gas and a nitrogen-containing gas (NH₃ gas) as a reactive gas has been described above, the present invention is also applicable to a method of forming a film using other gases. For example, the present invention can be applied to a method of forming a film containing oxygen, a method of forming a film containing nitrogen, a method of forming a film containing carbon, a method of forming a film containing boron, a method of forming a film containing a metal, a method of forming a film containing at least one selected from among these elements, etc. Examples of these films include an SiO film, an SiN film, an AlO film, a ZrO film, an HfO film, an HfAlO film, a ZrAlO film, a SiC film, a SiCN film, a SiBN film, a TiC film, a TiAlC film, etc. The characteristics (adsorbabilities, eliminabilities, vapor pressures, etc.) of a source gas and a reactive gas to be used to form these films may be compared and positions at which these gases are supplied or the internal structure of the shower head 234 may be appropriately changed to obtain desired effects.

With a substrate processing apparatus, a method of manufacturing a semiconductor device and a recording medium according to the present invention, characteristics of a semiconductor device may be improved.

### EXEMPLARY EMBODIMENTS OF THE INVENTION

Hereinafter, exemplary embodiments according to the present invention are supplementarily noted.

### Supplementary Note 1

According to an aspect of the present invention, there is provided a substrate processing apparatus including: a process chamber configured to process a substrate; a substrate support configured to support the substrate; a first gas supply unit including a first gas dispersion unit configured to disperse a first gas; a second gas supply unit including a second gas dispersion unit configured to disperse a second gas; and a plurality of dispersion pipes connecting the process chamber and the second gas dispersion unit by penetrating an inside of the first gas dispersion unit, wherein an area of an inner surface of the second gas dispersion unit is smaller than a sum of an area of an inner surface of the first gas dispersion unit and areas of outer surfaces of the plurality of dispersion pipes.

### Supplementary Note 2

In the substrate processing apparatus of Supplementary note 1, preferably, an area of a portion of the inner surface perpendicular to the substrate support is smaller than a sum of the areas of the outer surfaces of the plurality of dispersion pipes.

### Supplementary Note 3

In the substrate processing apparatus of Supplementary note 1, preferably, further includes a gas guide disposed in the second gas dispersion unit, and a sum of areas of a center portion and a peripheral portion of the gas guide is smaller than a sum of portions of the areas of the outer surfaces of the plurality of dispersion pipes opposite to a gas inlet port introducing the first gas.

### Supplementary Note 4

In the substrate processing apparatus of any one of Supplementary notes 1 through 2, preferably, the first gas includes a source gas and the second gas includes a reactive gas.

### Supplementary Note 5

In the substrate processing apparatus of any one of Supplementary notes 1 through 2, preferably, an amount of the second gas adsorbed per unit area is greater than that of the first gas.

### Supplementary Note 6

In the substrate processing apparatus of any one of Supplementary notes 1 through 5, preferably, further includes a control unit configured to control the first gas supply unit and the second gas supply unit to alternately supply the first gas and the second gas.

### Supplementary Note 7

In the substrate processing apparatus of any one of Supplementary notes 1 through 6, preferably, the first dispersion unit faces the substrate support, and the second dispersion unit is disposed on the first dispersion unit.

### Supplementary Note 8

In the substrate processing apparatus of any one of Supplementary notes 1 through 7, preferably, further includes: an inert gas supply unit configured to supply an inert gas; and a control unit configured to control the first gas supply unit, the second gas supply unit and the inert gas supply unit to supply the inert gas to the second dispersion unit when the first gas is supplied to the first dispersion unit and supply the inert gas to the first dispersion unit when the second gas is supplied to the second dispersion unit.

### Supplementary Note 9

In the substrate processing apparatus of any one of Supplementary notes 1 through 8, preferably, further includes: a thermal insulation unit disposed between the substrate support and the first dispersion unit.

### Supplementary Note 10

In the substrate processing apparatus of Supplementary note 9, preferably, the thermal insulation unit includes a vacuum layer.

### Supplementary Note 11

According to another aspect of the present invention, there is provided a method of manufacturing a semiconductor device including: (a) supplying a first gas to a substrate accommodated in a process chamber through a first dispersion unit; and (b) supplying a second gas to the substrate through a second gas dispersion unit and a plurality of dispersion pipes connecting the process chamber and the second gas dispersion unit by penetrating an inside of the first gas dispersion unit, wherein an area of an inner surface of the second gas dispersion unit is smaller than a sum of an area of an inner surface of the first gas dispersion unit and areas of outer surfaces of the plurality of dispersion pipes.

### Supplementary Note 12

In the method of Supplementary note 11, preferably, an amount of the second gas adsorbed per unit area is greater than that of the first gas.

### Supplementary Note 13

In the method of any one of Supplementary notes 10 and 12, preferably, the steps (a) and (b) are alternately performed.

### Supplementary Note 14

In the method of any one of Supplementary notes 11 through 13, preferably, further including: supplying an inert gas to the second dispersion unit when the first gas is supplied in the step (a); and supplying the inert gas to the first dispersion unit when the second gas is supplied in the step (b).

### Supplementary Note 15

In the method of Supplementary note 14, preferably, further including: exhausting the first gas through a first exhaustion port connected to the first dispersion unit while supplying the inert gas after performing the step (a); and exhausting the second gas through a second exhaustion port connected to the second dispersion unit while supplying the inert gas after performing the step (b).

### Supplementary Note 16

According to still another aspect of the present invention, there is provided a program causing a computer to perform: (a) supplying a first gas to a substrate accommodated in a process chamber through a first dispersion unit; (b) supplying a second gas to the substrate through a second gas dispersion unit and a plurality of dispersion pipes connecting the process chamber and the second gas dispersion unit by penetrating an inside of the first gas dispersion unit, wherein an area of an inner surface of the second gas dispersion unit is smaller than a sum of an area of an inner surface of the first gas dispersion unit and areas of outer surfaces of the plurality of dispersion pipes.

### Supplementary Note 17

In the program of Supplementary note 16, preferably, an amount of the second gas adsorbed per unit area is greater than that of the first gas.

### Supplementary Note 18

In the program of any one of Supplementary notes 16 through 17, preferably, further including: supplying an inert gas to the second dispersion unit when the first gas is supplied in the sequence (a); and supplying the inert gas to the first dispersion unit when the second gas is supplied in the sequence (b).

### Supplementary Note 19

In the program of Supplementary note 18, preferably, further including: exhausting the first gas through a first exhaustion port connected to the first dispersion unit while supplying the inert gas after performing the sequence (a); and exhausting the second gas through a second exhaustion port connected to the second dispersion unit while supplying the inert gas after performing the sequence (b).

### Supplementary Note 20

According to still another aspect of the present invention, there is provided a non-transitory computer-readable recording medium storing a program causing a computer to perform: (a) supplying a first gas to a substrate accommodated in a process chamber through a first dispersion unit; and (b) supplying a second gas to the substrate through a second gas dispersion unit and a plurality of dispersion pipes connecting the process chamber and the second gas dispersion unit by penetrating an inside of the first gas dispersion unit, wherein an area of an inner surface of the second gas dispersion unit is smaller than a sum of an area of an inner surface of the first gas dispersion unit and areas of outer surfaces of the plurality of dispersion pipes.

### Supplementary Note 21

In the non-transitory computer-readable recording medium of Supplementary note 20, preferably, an amount of the second gas adsorbed per unit area is greater than that of the first gas.

### Supplementary Note 22

In the non-transitory computer-readable recording medium of Supplementary notes 20 through 21, further including: supplying an inert gas to the second dispersion unit when the first gas is supplied in the sequence (a); and supplying the inert gas to the first dispersion unit when the second gas is supplied in the sequence (b).

### Supplementary Note 23

In the non-transitory computer-readable recording medium of Supplementary note 22, preferably, further including: exhausting the first gas through a first exhaustion port connected to the first dispersion unit while supplying the inert gas after performing the sequence (a); and exhausting the second gas through a second exhaustion port connected to the second dispersion unit while supplying the inert gas after performing the sequence (b).

### Supplementary Note 24

According to still another aspect of the present invention, there is provided a substrate processing apparatus or an apparatus of manufacturing a semiconductor device including: a process chamber configured to process a substrate; a substrate support configured to support the substrate; a first gas supply unit including a first gas dispersion unit configured to disperse a first gas; a second gas supply unit including a second gas dispersion unit configured to disperse a second gas; and a plurality of dispersion pipes connecting the process chamber and the second gas dispersion unit by penetrating an inside of the first gas dispersion unit, wherein a surface area of a second retention region where the second gas remains without facing a mainstream of the second gas is smaller than that of a first retention region where the first gas remains without facing a mainstream of the first gas.

1. A substrate processing apparatus comprising:
a process chamber configured to process a substrate;
a substrate support configured to support the substrate;
a first gas supply unit including a first buffer space configured to disperse a first gas;
a second gas supply unit including a second buffer space configured to disperse a second gas;
a plurality of dispersion pipes connecting the process chamber and the second buffer space by penetrating an inside of the first buffer space and configured to supply the second gas into the process chamber; and
a gas guide having a cone shape disposed in the second buffer space wherein a lower end of the gas guide extends in a horizontal direction beyond a region where the plurality of dispersion pipes are installed,
wherein an area of a space of the gas guide where gas molecules in the second buffer space hardly penetrate is smaller than a sum of an area of an inner surface of the first buffer space and areas of outer surfaces of the plurality of dispersion pipes.

2. The substrate processing apparatus of claim 1, wherein an area of a portion of the inner surface perpendicular to the substrate support is smaller than a sum of the areas of the outer surfaces of the plurality of dispersion pipes.

3. The substrate processing apparatus of claim 1, wherein a sum of areas of a center portion and a peripheral portion of the gas guide is smaller than a sum of portions of the areas of the outer surfaces of the plurality of dispersion pipes opposite to a gas inlet port introducing the first gas.

4. The substrate processing apparatus of claim 2, wherein a sum of areas of a center portion and a peripheral portion of the gas guide is smaller than a sum of portions of the areas of the outer surfaces of the plurality of dispersion pipes opposite to a gas inlet port introducing the first gas.

5. The substrate processing apparatus of claim 1, wherein the first gas comprises a source gas and the second gas comprises a reactive gas.

6. The substrate processing apparatus of claim 1, wherein an amount of the second gas adsorbed per unit area is greater than that of the first gas.

7. The substrate processing apparatus of claim 3, wherein an amount of the second gas adsorbed per unit area is greater than that of the first gas.

8. The substrate processing apparatus of claim 1, further comprising a control unit configured to control the first gas supply unit and the second gas supply unit to alternately supply the first gas and the second gas.

9. The substrate processing apparatus of claim 1, wherein the first buffer space faces the substrate support, and the second buffer space is disposed on the first buffer space.

10. The substrate processing apparatus of claim 6, wherein the first buffer space faces the substrate support, and the second buffer space is disposed on the first buffer space.

11. The substrate processing apparatus of claim 7, wherein the first buffer space faces the substrate support, and the second buffer space is disposed on the first buffer space.

12. The substrate processing apparatus of claim 1, further comprising:
an inert gas supply unit configured to supply an inert gas; and
a control unit configured to control the first gas supply unit, the second gas supply unit and the inert gas supply unit to supply the inert gas to the second buffer space when the first gas is supplied to the first buffer space and supply the inert gas to the first buffer space when the second gas is supplied to the second buffer space.

13. The substrate processing apparatus of claim 1, further comprising: a thermal insulation unit disposed between the substrate support and the first buffer space to face the substrate.

14. The substrate processing apparatus of claim 13, wherein the thermal insulation unit comprises a vacuum space.

15. The substrate processing apparatus of claim 3, further comprising: a thermal insulation unit disposed between the substrate support and the first buffer space.

16. he substrate processing apparatus of claim 15, wherein the thermal insulation unit comprises a vacuum space.

17. The substrate processing apparatus of claim 11, further comprising: a thermal insulation unit disposed between the substrate support and the first buffer space.

18. The substrate processing apparatus of claim 17, wherein the thermal insulation unit comprises a vacuum space.

19. The substrate processing apparatus of claim 1, wherein a surface area of a second retention region where the second gas remains without facing a mainstream of the second gas is smaller than that of a first retention region where the first gas remains without facing a mainstream of the first gas.
